(19) United States
(12) Patent Application Publication
(10) Pub. No.: US 2018/0302999 A1
(43) Pub. Date: Oct. 18, 2018

(54) DRIVE TRAIN FOR A MOTOR VEHICLE AND PRINTED CIRCUIT BOARD ARRANGEMENT FOR IT

(71) Applicants: GETRAG B.V. & CO. KG, Untergruppenbach (DE); FORD-WERKE GMBH, Köln (DE)

(72) Inventors: Heiko SÖHNER, Bad Rappenau (DE); Johann Kirchhoffer, Köln (DE); Thomas BRANDT, Edelsfeld (DE); Peter SCHROLL, Nürnberg (DE)

(21) Appl. No.: 15/771,969

(22) PCT Filed: Oct. 7, 2016
(86) PCT No.: PCT/EP2016/074048

§ 371 Date: Jun. 11, 2018

(30) Foreign Application Priority Data
Oct. 29, 2015 (DE) 10 2015 118 452.4

(51) Int. Cl. H05K 5/00; H05K 7/20

(52) U.S. Cl. CPC H05K 5/0082; H05K 5/006; H05K 7/20854

(57) ABSTRACT

A circuit board arrangement with a printed circuit board and with a circuit board carrier on which the printed circuit board is mounted, in particular for a motor vehicle drive train electronic module. The printed circuit board has a central region and a peripheral region. The printed circuit board is held in the central region on the circuit board carrier in a tangential direction in a positive-locking manner or with a first transverse force in a non-positive manner. The circuit board is held in the peripheral region on the circuit board carrier in a tangential direction with a second transverse force which is smaller than the first transverse force.

### CROSS-REFERENCE TO RELATED APPLICATIONS

This application is based on International patent application PCT/EP 2016/074048, filed Oct. 7, 2016, which claims the priority of the German patent application DE 10 2015 118 452.4, filed Oct. 29, 2015, the entire content of these earlier applications being incorporated herein by reference.

### FIELD

The present application relates to a circuit board arrangement comprising a printed circuit board and a circuit board carrier on which the printed circuit board is mounted, in particular for an electronic module of a drive train of a motor vehicle, the printed circuit board having a central region and a peripheral region.

Furthermore, the present application relates to a drive train for a motor vehicle, comprising an electronic module adapted to control at least a part of the drive train, wherein the electronic module has a housing in which a circuit board arrangement of the type described above is accommodated.

### BACKGROUND

Printed circuit board arrangements of the type described above are generally known. The printed circuit boards, which can also be called circuit boards or plates, contain passive and/or active electrical and/or electronic components, such as resistors, capacitors, transistors, processors, thyristors, etc. Furthermore, the individual components of such a printed circuit board are connected to each other via electrical connection lines, which can, for example, be made of solder. Some of these components consume a comparatively high power and generate heat that must be dissipated as effectively as possible. It is therefore known to produce a printed circuit board carrier from a thermally conductive material, for example in the form of a housing portion made of a housing material such as aluminum or the like. Furthermore, it is known to provide cooling fins on such a circuit board carrier on the side facing away from the printed circuit board.

Further boundary conditions are also important for the application of such circuit board arrangements for drive trains for vehicles. On the one hand, the ambient temperature range can vary widely, for example from 40° C. to +100° C. and above. Furthermore, circuit board arrangements in such environments are exposed to considerable mechanical disturbances, especially in the form of vibrations.

If power semiconductor components such as thyristors are also mounted on the printed circuit board or in the area of the printed circuit board, the requirements with regard to heat dissipation increase significantly.

It is therefore known, for example, to bond and screw together a printed circuit board with its side facing the circuit board carrier, so that heat can be dissipated optimally. The bonding is preferably made heat conductive.

Due to vibrations and high temperature loads, deformations can occur on the circuit board carrier, which the printed circuit board must follow in the case of rigid mounting. This can result in small cracks in the plate, for example hairline cracks, which can lead to rapid aging of the printed circuit board and the soldering points provided on it. With a bonded or glued printed circuit board it is difficult or impossible to replace the printed circuit board.

In order to avoid uncontrolled vibrations, it is also known to clamp or braise a printed circuit board in a housing. Deflections which occur in this arrangement, can, however, be problematic. Horizontal relative movements between a printed circuit board and components mounted thereon can also be problematic.

### SUMMARY

Against this background, it is an object of the present application to provide an improved circuit board arrangement as well as an electronic module of a drive train equipped therewith, wherein the circuit board arrangement is preferably optimized with regard to influences of oscillations or vibrations on the printed circuit board and/or with regard to the dissipatibility of heat. Furthermore, good interchangeability of the printed circuit board is preferable, and a small installation space requirement is preferable as well.

In the circuit board arrangement mentioned at the outset, the above object is solved according to a first aspect of the present application in that the printed circuit board is held in the central region on the circuit board carrier in a tangential direction by means of a positive-locking manner or by means of a first transverse force in a non-positive manner, wherein the circuit board is held in the peripheral region on the circuit board carrier in the tangential direction by means of a second transverse force which is smaller than the first transverse force.

With the way in which the printed circuit board is held on the circuit board arrangement, it is firstly possible to accommodate changes in the length of the printed circuit board in the tangential direction due to temperature changes, since such expansions in the tangential direction can take place in the peripheral region due to the low second transverse force. The second transverse force is preferably chosen such that the printed circuit board can detach or slip against the mounting with respect to the circuit board carrier. This can help to prevent or at least to reduce a deflection of the printed circuit board together with a displacement in an axial direction (perpendicular to the extension of the printed circuit board).

The mountings or supports of the printed circuit board in the central region and in the peripheral region are designed preferably such that no or only a small deflection or displacement is possible in an axial direction (i.e. perpendicular or normal to the extension of the printed circuit board and transverse to the tangential direction).

As a consequence, high temperature loads do not lead to excessive deformation of the printed circuit board, especially in the automotive sector. On the other hand, it is possible that the printed circuit board can compensate for any changes in the shape of the circuit board carrier.

As a consequence, the service life of the printed circuit board and its solder joints can be increased.

The printed circuit board is preferably a relatively large printed circuit board, for example with dimensions of at least 10 cm in length and/or width, preferably at least 15 cm in at least length or width. It is also advantageous if there is provided only a single support or mounting with respect to circuit board carrier in the central region, or if the number of supports or mountings in the central region or is smaller than or equal to 3. In the peripheral region, the number of supports or mountings, on which the printed circuit board is held by means of a second transverse force, is preferably less than 10, in particular less than 7.

In the central region or area, the printed circuit board can be held in a positive-locking manner also in the axial direction (perpendicular to the tangential direction).

The mounting of the printed circuit board with respect to the circuit board carrier is preferably detachable. Preferably, the printed circuit board is not bonded or glued to the circuit board carrier. As a consequence, better repair capability can also be achieved in these preferred embodiments.

The ratio of the first transverse force to second transverse force is preferably greater than 1.5:1, especially greater than 2:1, preferably greater than 5:1, and particularly preferred greater than 10:1. This ratio is infinite in case of a positive-locking mounting on the tangential direction in the central region. The ratio of the first transverse force to the second transverse force is preferably smaller than 100:1 in case of a non-positive locking mounting of the printed circuit board in the central region.

The object is thus achieved in full.

According to a particularly preferred embodiment, the printed circuit board is mounted in the peripheral region or area and/or in the central region in a manner so as to be displaceable in the tangential direction with respect to the circuit board carrier.

The displaceable or sliding mounting in the peripheral region allows in particular a linear expansion in the tangential direction in the event of temperature changes.

The displaceable mounting in the tangential direction is, however, preferably limited. For example, the printed circuit board may be fixed in the central region and/or in the peripheral region by means of fastening elements such as screws on the circuit board carrier, which fastening elements extend axially through a recess in the circuit board. In this case, the size of the recess in relation to the thickness of the fastening element may allow and limit the tangential displacibility.

According to a further preferred embodiment, the first transverse force and/or the second transverse force are produced by a respective axial clamping device.

Such a clamping device can act in an axial direction in a positive-locking manner on the printed circuit board, and may particularly connect the printed circuit board in the axial direction in a positive-locking manner with the circuit board carrier. In this case, the axial clamping force together with friction coefficients between the surfaces involved determine the respective transverse force with which the axial clamping device holds the printed circuit board in the tangential direction.

As mentioned above, an axial clamping force can be generated, for example, by means of fastening elements such as screws. In some cases, however, such an axial clamping force can also be generated by the circuit board carrier or an element rigidly connected thereto, such as a housing element, pressing against the printed circuit board in a controlled manner.

An axial clamping device can, for example, be implemented using a screw. In this case, the axial clamping force and the respective transverse force can be adjusted via the torque with which the screw is fixed or screwed in.

According to a particularly preferred embodiment, however, the printed circuit board is held in the peripheral region and/or in the central region by means of a spring element and/or by means of a damper element in relation to the circuit board carrier.

In this embodiment, the printed circuit board can be decoupled from vibrations of the circuit board carrier in a favorable manner.

If such a mounting contains a spring element, the transverse force exerted by this mounting on the printed circuit board is determined, inter alia, by the spring constant of that spring element.

It is particularly preferred if the printed circuit board is held in the central region axially positive with respect to the circuit board carrier, and if the printed circuit board is held in the peripheral region by means of one or several mountings using a spring element and/or a damper element, in relation to the circuit board carrier.

The spring element and the damper element can be formed by a single element, for example an elastically deformable element that provides some damping during deformation. Such elastic elements can be made from an elastic plastic material or rubber material, for example. Such elastic elements can, for example, be formed by ring elements which are arranged between a head of a fastening element and the printed circuit board. In some cases an intermediate element can be inserted between the head of the fastening element and the elastic element, like for example a shim disk, a spacer or the like.

It is also possible for the mounting of the printed circuit board in relation to the circuit board carrier is made such that a spring element and/or a damper element is arranged on one axial side of the printed circuit board and acts on the printed circuit board on the one side for establishing the mounting. In some embodiments it is possible that a spring element and/or a damper element is arranged on both axial sides of the printed circuit board, such that the printed circuit board is held in the area of this mounting on both axial sides by means of such an axially displaceable bearing. For example, elastic rings can be arranged at an upper and a lower end of a recess in the printed circuit board, which recess is penetrated by a fastening screw, wherein the elastic rings are also penetrated by the screw, which screw is screwed into the circuit board carrier.

According to a further preferred embodiment, the spring element and/or the damper element provides an electrical connection between the printed circuit board and the circuit board carrier.

In this case, the spring element and/or the damper element is preferably made from an electrically conducting material, for example in the form of a metal spring, in the form of a metal spring band or in the form of a metal spring cushion.

This measure can be used for realizing an equalization of potentials. The printed circuit board can have in this case an electrically conducting through-plating or via in the area in which such electrically conducting element engages the printed circuit board, in order to electrically connect the circuit board carrier with a fastening device or with another housing portion in order to realize this equalization of potentials or equipotential condition.

According to a second aspect, the circuit board carrier comprises a planar portion which faces the printed circuit board and which is aligned substantially parallel thereto, wherein the circuit board carrier serves as a heat sink and wherein a heat-conducting material is arranged between the printed circuit board and the planar portion.

The heat-conducting material may take the form of cushions, pads, foam, thermally conductive plates or similar. The heat-conducting material is preferably a material that can be separated from the printed circuit board, wherein the separation does not lead to a destruction of the printed circuit board. The heat-conducting material is, as a consequence, preferably not an adhesive. The heat-conducting material is especially designed to allow a tangential displacibility between the printed circuit board and the circuit board carrier. The heat-conducting material can be an elastically deformable material.

It is of particular advantage when the heat-conducting material is formed as a paste.

Such a heat-conducting paste is preferably deformed in a non-elastic manner when the circuit board arrangement is produced, so that a flat, intimate connection or heat-conducting bridge is created between the printed circuit board and the circuit board carrier, without straining the printed circuit board.

The paste is preferably not cured, preferably not dried and preferably not melted.

In accordance with the present application, the heat-conducting paste is preferably applied in a thickness in the range of 100 μm to 600 μm, in particular 250 μm to 450 μm. In this case, it is preferred if spacers are provided between the printed circuit board and the circuit board carrier, which spacers ensure that the printed circuit board is held in such a distance from the circuit board carrier, and that the heat-conducting paste has such an axial thickness. The spacers can be axially form-fitting or positive locking elements, but may also be formed by elastic elements which serve to mount the printed circuit board.

Such spacers may also be used to limit the tangential expansion of the heat-conducting paste, and in particular to prevent the heat-conducting paste from entering an area of a mounting or a fastening device, such as for example the area of a threaded hole for a screw or the like.

The heat-conducting material preferably contains beads made of an electrically isolating material, in particular glass, whose diameter defines a minimum layer thickness.

Short circuits between the printed circuit board and the circuit board carrier can be avoided in this way. A side of the printed circuit board which faces the circuit board carrier, preferably contains uninsulated test points and/or so-called vias. Such vias can not only be used for the electrical connection of several layers, but may also be used for an improved heat dissipation, such that such a via can extend to the underside.

The embodiment in which the heat-conducting paste is arranged between the printed circuit board and the circuit board carrier, is preferably associated with an embodiment in which the printed circuit board is held in its peripheral region by means of a relatively small second transverse force, wherein, in this case, the planar portion of the circuit board carrier is arranged essentially between the central region and the peripheral region.

The planar portion within which the heat-conducting paste is arranged, may in this case include parts of the central region and/or parts of the peripheral region, but preferably lies tangentially next to any mounting or holding portions. Here, the heat-conducting paste is preferably located within a sealed area of a housing within which the circuit board arrangement is provided.

The circuit board arrangement may be used in many applications. However, the circuit board arrangement is of particular advantage when used in an environment with strong temperature fluctuations and/or strong vibrations.

Accordingly, a further aspect lies in a drive train for a motor vehicle, comprising an electronic module which is adapted to control at least a part of the drive train, wherein the electronic module has a housing in which a circuit board arrangement described above is accommodated.

Here, the housing can be at least partially formed by a housing of the drive train. For example, a part of the housing can be designed as a housing base which is connected integrally with a transmission housing. The circuit board carrier may for example be formed by a housing cover or lid, which covers the housing base and seals in the peripheral region.

The circuit board arrangement may have a single printed circuit board, but may also have a second printed circuit board aligned substantially in parallel thereto. In this case, it is preferred if the two printed circuit boards are connected to each other in a positive-locking manner in the axial direction in the central region by means of a spacer sleeve. Further, it is preferred in this case if the highly heat-generating components of such a circuit board arrangement are provided on that printed circuit board which is adjacent to the circuit board carrier, and if this printed circuit board is connected to the circuit board carrier at least partially via a heat-conducting paste.

In the peripheral region, the mounting of the lower and/or of the upper printed circuit board may be realized by means of elastically deformable elements such as O-rings or the like, and/or by means of metal springs or metal cushions. In the peripheral region, the mounting can be made by means of fastening elements such as clamping screws, but may be made alternatively or additionally using housing sections which exert a defined axial clamping force on the printed circuit board in the installed state, preferably via an elastomer element and/or via a metal spring or a metal cushion.

As explained, the mounting can be made in the peripheral region such that a clamping screw presses via an axially deformable element against one axial side of the printed circuit board. In a preferred variant, however, such axially deformable elements such as elastomer elements, metal spring bands or metal spring cushions, are arranged on both axial sides of a printed circuit board and are pressed by means of a suitable clamping screw against the circuit board carrier, such that the printed circuit board can be deflected from a standard position in both axial directions.

A clamping sleeve used for this purpose, which acts, for example, between a bottom side of a screw head and a top side of such an axially deformable element, can be connected to the circuit board carrier via a stop, in order to achieve a defined axial position of this clamping sleeve.

Overall, a printed circuit board can be mounted with little distortion in relation to a circuit board carrier. Temperature changes can be well absorbed. The printed circuit board, preferably, is largely decoupled from vibrations and against plastic deformation of the circuit board carrier, so that such influences on the printed circuit board can be reduced, whereby the service life of the printed circuit board and the solder connections provided thereon can be improved.

In many cases, it is also possible to replace the printed circuit board during repair. Furthermore, the required installation space is small.

The printed circuit board may have plug connectors that are rigidly connected to the printed circuit board. However, especially if the plug connector is provided in the peripheral region, it may be preferred if the plug connector is not rigidly connected to the printed circuit board, but is decoupled from the printed circuit board in a similar manner. A connector or plug connector of this type can also be connected to the printed circuit board by means of an electrical connection line or cable, so that relative movements between the plug connector and the printed circuit board are possible.

The present design makes it possible to absorb both deflections of the printed circuit board as well as axial thermal expansions of the printed circuit board, so that no stresses or strains are caused hereby. In addition, micro-bending or distortions of the printed circuit board can be absorbed.

The distribution of components on the printed circuit board or the definition of the central region and the peripheral region are preferably such that preferably only those components are arranged in the central region on the printed circuit board, which are less sensitive to thermal loads and/or vibration loads. Critical components or components with critical solder connections are preferably arranged in the peripheral region.

In some variants it is possible to fasten the printed circuit board as a whole using elastic clamping devices with low clamping forces, not only in the peripheral region, but also in the central region.

In this case it is necessary to decouple any connector of the printed circuit board against the printed circuit board itself, by mounting such connector on the circuit board carrier or on a housing portion connected rigidly thereto, and to realize a flexible connection between the connector and the printed circuit board.

In all variants, it is preferred if radial gaps in tangential direction between such a screw and the printed circuit board are established in the area of mountings by means of screws, to ensure tangential displacibility.

Overall, depending on the embodiment, at least one of the following advantages can be achieved. A higher resistance to vibrations can be achieved, if suitable spring and/or damper elements are installed. Vertical and horizontal thermal expansions are absorbed with little stress due to low friction and low clamping forces. Deflections of the printed circuit board due to shock loads and elastic deformations of the circuit board carrier are slight or limited. In some embodiments, a clamping arrangement may have a spring property and/or a damping property at the same time, as well as an electrical conductivity, particularly for producing ground connections or for the purpose of electrical equalization of potentials. Damage and bending of the printed circuit board during assembly can be avoided. Loads on any pressed-in connectors on the printed circuit board which carry electrical power or signals, can be avoided or reduced.

It is understood that the features mentioned above and those to be explained below can be used not only in the combination indicated, but also in other combinations or individually, without leaving the scope of the present invention.

### BRIEF DESCRIPTION OF THE SEVERAL VIEWS OF THE DRAWING

Embodiments are shown in the drawing and are explained in more detail in the following description. The drawings show:

FIG. 1 a schematic longitudinal sectional view through an electronic module having an embodiment of a circuit board arrangement;

FIG. 2 a top view of the circuit board arrangement of FIG. 1;

FIG. 3 a schematic sectional view through an embodiment of a central fastening device;

FIG. 4 a schematic sectional view through an embodiment of a peripheral fastening device;

FIG. 5 a schematic sectional view through a further embodiment of a peripheral fastening device;

FIG. 6 a schematic view of an embodiment of a drive train for a motor vehicle;

FIG. 7 a schematic sectional view through a further embodiment of a central fastening device; and

FIG. 8 a schematic sectional view through another embodiment of a peripheral fastening device.

### EMBODIMENTS

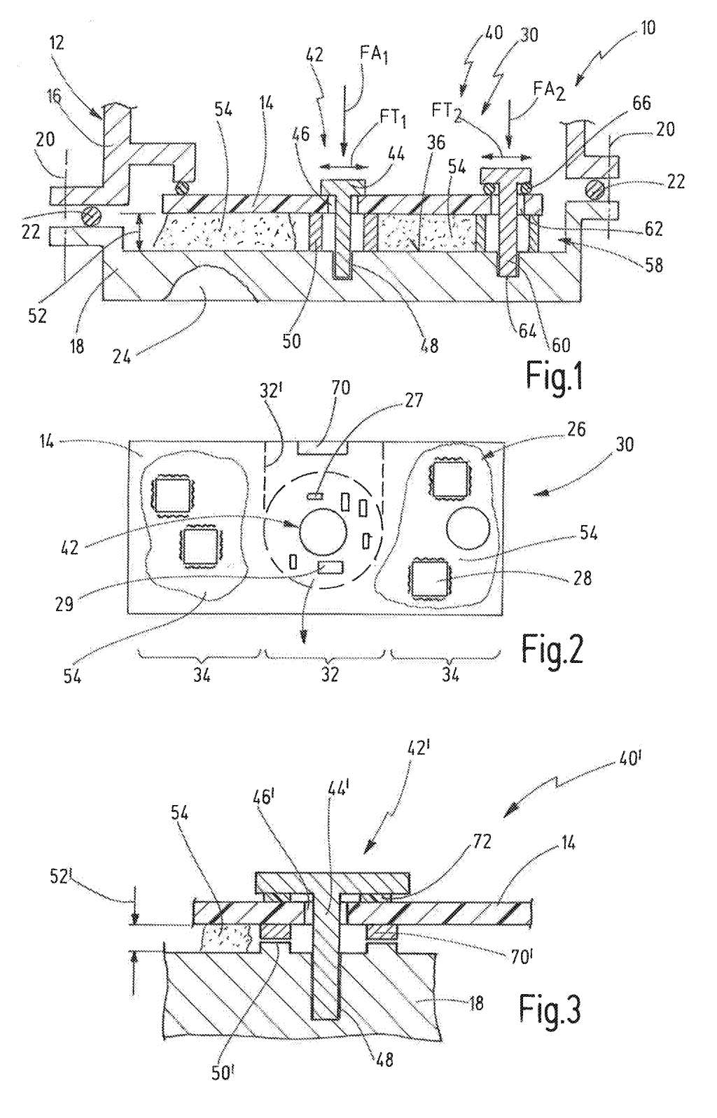

In FIGS. 1 and 2, an electronic module 10 for a motor vehicle drive train is shown schematically and is generally designated as 10.

The electronic module 10, which can be adapted in particular to control at least a part of a drive train, comprises a housing arrangement 12, within which at least one printed circuit board 14 is arranged. The printed circuit board 14, also known as a circuit board or plate, comprises in a known manner a dielectric plate on which electrical and electronic components, solder joints, conductor traces, vias, etc. can be formed.

The housing arrangement 12 comprises a housing base 16, which can be part of a drive train housing, for example, part of a transmission housing. The housing base 16, for example, can be made of a metal, particularly a steel alloy, an aluminum alloy or the like, and is preferably produced by casting.

The housing arrangement 12 further, comprises a housing cover 18 connected to the housing base 16 via a screw arrangement 20, such that a sealing arrangement 22 seals an interior of the housing arrangement 12, within which the printed circuit board 14 is arranged. The housing cover 18, for example, can be made of a material having good heat-conducting properties, such as an aluminum alloy, and can have one or more cooling fins 24 on an outside facing away from the interior of the housing arrangement 12, as is shown schematically in FIG. 1.

As can be seen in FIG. 2 in particular, electronic components can be attached to the printed circuit board 14, which may, for example, include passive electric components 27 such as resistors, capacitors, coils, as well as active components such as transistors which are not designated in detail. Furthermore, the electronic components may contain processors 28, which have a large number of contact pins, as is schematically indicated in FIG. 2. In addition, the electronic components 26 may include power electronic components 29, such as for example thyristors or the like for controlling electrical consumers such as electrical actuators of a transmission or the like.

The printed circuit board 14 is connected to the housing cover 18 via a fastening arrangement schematically shown at 30, which housing cover 18 thus forms a circuit board carrier.

As can be seen in FIG. 2, the printed circuit board 14 is essentially divided into a central region 32 and a peripheral region 34 or peripheral regions 34. The central region 32 may be an area which is completely enclosed by a peripheral region 34. The central region 32 may, however, also be connected to a boundary of the printed circuit board, as is schematically indicated in FIG. 2 at 32′.

FIG. 2 shows that those components, which are relatively insensitive to vibrations or which have solder joints which are relatively insensitive to vibrations, are arranged in the central region 32, whereas those components which are susceptible to vibrations or bends of the printed circuit board, or which have solder joints that are susceptible to vibrations of bends of the printed circuit board, are arranged in the peripheral region 34.

FIG. 1 also shows that the printed circuit board 14 is arranged substantially parallel to a planar portion 36 of the housing cover 18, wherein the planar portion 36 faces the interior of the housing arrangement 12.

The printed circuit board 14, the part of the housing cover 18 which is associated to the printed circuit board 14, and the fastening arrangement 30 form a circuit board arrangement 40.

The fastening arrangement 30 of the circuit board arrangement 40 comprises a central fastening device 42. The central fastening device 42 serves to fasten or hold the printed circuit board in the central region 32 at the housing cover 18. Here, the printed circuit board 14 is held by the central fastening device 42 on the circuit board carrier or on the housing cover 18 in a tangential direction with a first transverse force FT₁. This means that the printed circuit board 14 can be moved in the tangential direction with respect to the circuit board carrier 18 within the central region 32, if a force is exerted which is greater than the first transverse force FT₁.

In this case, a tangential direction or radial direction means in particular a direction that extends in parallel to the extension of the printed circuit board 14. Axial directions are generally directions which are aligned transverse, in particular perpendicular to the extension of the printed circuit board, unless otherwise stated.

In this case, the printed circuit board 14 is held in the central region 32 by means of a central fastening device 42 in the form of a clamping device. Here, the central fastening device 42 includes a central fastening bolt 44, which is passed through a central fastening recess 46 in the printed circuit board 14 and which is screwed into a central fastening bolt receptacle 48 in the circuit board carrier 18. A head of the central fastening bolt 44, which head is not designated in detail, rests on an axial side of the printed circuit board 14. A spacer element 50 is arranged between the other axial side of the printed circuit board 14 and the circuit board carrier 18, which spacer element 50 can be designed as an independent element or as a part of the circuit board carrier 18.

The printed circuit board 14 is slidably mounted in a tangential direction relative to the circuit board support 18, in that a diameter of the central fastening recess 46 is larger than a diameter of a shaft of the central fastening bolt 44, so that a radial gap is provided therebetween.

The spacer element 50 defines a distance 52 between the printed circuit board 14 and the planar portion 36 of the circuit board carrier 18 (housing cover).

It can be seen in FIG. 1 that a heat-conducting material is arranged between the printed circuit board 14 and the planar portion 36, particularly in the form of a heat-conducting paste 54. The distance 52 may have a dimension in a range from 1 mm to 5 mm.

The fastening arrangement 30, further, comprises a peripheral fastening device 58. The peripheral fastening device 58 comprises one or more peripheral fastening bolt(s) 60, by means of which the printed circuit board 14 is screwed to the circuit board carrier 18 in the peripheral region 34. The peripheral fastening device 58, further includes a peripheral fastening recess 62 in the printed circuit board 14, through which the peripheral fastening bolt 60 is guided. A peripheral fastening bolt receptacle 64 is provided in the circuit board carrier 18, which peripheral fastening bolt receptacle 64 may, for example, be formed as a threaded hole, like the central fastening bolt receptacle 48.

Furthermore, the peripheral fastening device 58 comprises at least one peripheral fastening element 66 which is arranged between a head of the peripheral fastening bolt 60 and the printed circuit board 14. The peripheral fastening element 66 may, for example, be formed as an elastic ring, as a metal spring, a metal cushion or the like. Preferably, the peripheral fastening element 66 has a certain axial elastic deformability.

The peripheral fastening device 58 is designed so that the printed circuit board 14 is held on the circuit board carrier 18 in the peripheral region 34 with a second transverse force FT₂ in the tangential direction, which second transverse force FT₂ is smaller than the first transverse force FT₁.

FIG. 1 shows that the central fastening bolt 44 can be screwed tightly so as to adjust the first transverse force FT₁, such that the central fastening bolt 44 acts with a first axial force FA₁ on the printed circuit board 14, in order to axially clamp the printed circuit board 14 in the central region, so as to establish the first transverse force FT₁. Furthermore, FIG. 1 shows that the peripheral fastening bolt 60 acts with a second axial force FA₂ on the printed circuit board 14, in order to adjust the second transverse force FT₂.

The transverse forces FT₁, FT₂ depend on the one hand from the axial forces FA₁, FA₂, but also on friction pairings, for example between a bolt head and the printed circuit board and/or between the spacer element and the printed circuit board. In this context, it should be mentioned that the peripheral fastening device 58 preferably also has a spacer element, which is not shown or designated in detail in FIG. 1 for reasons of clarity, but whose function corresponds to that of the spacer element 50 of the central fastening device 42.

The second transverse force FT₂ can already be smaller than the first transverse force FT₁, since the peripheral fastening device 58 comprises the peripheral fastening element 66 (at equal forces FA₁, FA₂). In some cases, however, the central fastening device 42 may also contain such an element. In this case, it is preferable to ensure in a different way that the second transverse force FT₂ is smaller than the first transverse force FT₁.

FIG. 2 also shows that an electrical plug connection device 70 may be provided on the printed circuit board 14, which is connected to the printed circuit board 14. Electrical signals and/or electrical power may be transmitted via the plug connection device 70, for example to supply the printed circuit board with power and/or to transmit the power of power electronic components 29.

In case that the electrical plug connection device 70 is fixed to the central region, the plug connection device can be rigidly connected to the printed circuit board 14. In other cases, it can be preferred to fix the plug connection device 70 to the housing arrangement 12. In this case, a flexible cable shall be provided between the plug connection device 70 and the printed circuit board 14.

The following figures describe further embodiments of circuit board arrangements which generally correspond to the circuit board arrangement 40 of FIGS. 1 and 2 in terms of design and function. Identical elements are therefore identified by identical reference numerals. In the following, essentially the differences are explained.

FIG. 3 shows a schematic sectional view through a further embodiment of a central fastening device 42′ of a circuit board arrangement 40′.

In the central fastening device 42′, a distance 52′ between the printed circuit board 14 and the circuit board carrier 18 is established by means of a spacer element 50′, which extends from the circuit board carrier 18 towards the printed circuit board 14. However, a portion of an electrical plug connection device 70′ is formed between the spacer element 50′ and the printed circuit board 14, which plug connection device 70′, together with the spacer element 50′, defines the distance 52′.

Furthermore, a central fastening clamping element 72 is arranged between a head of the bolt 44′, not specified in detail, and the printed circuit board 14, which central fastening clamping element 72 can be designed in a manner similar to the peripheral fastening element 66 of the type described above.

Such a central fastening device 42′ may be used in conjunction with any of the peripheral fastening devices described above and those described below.

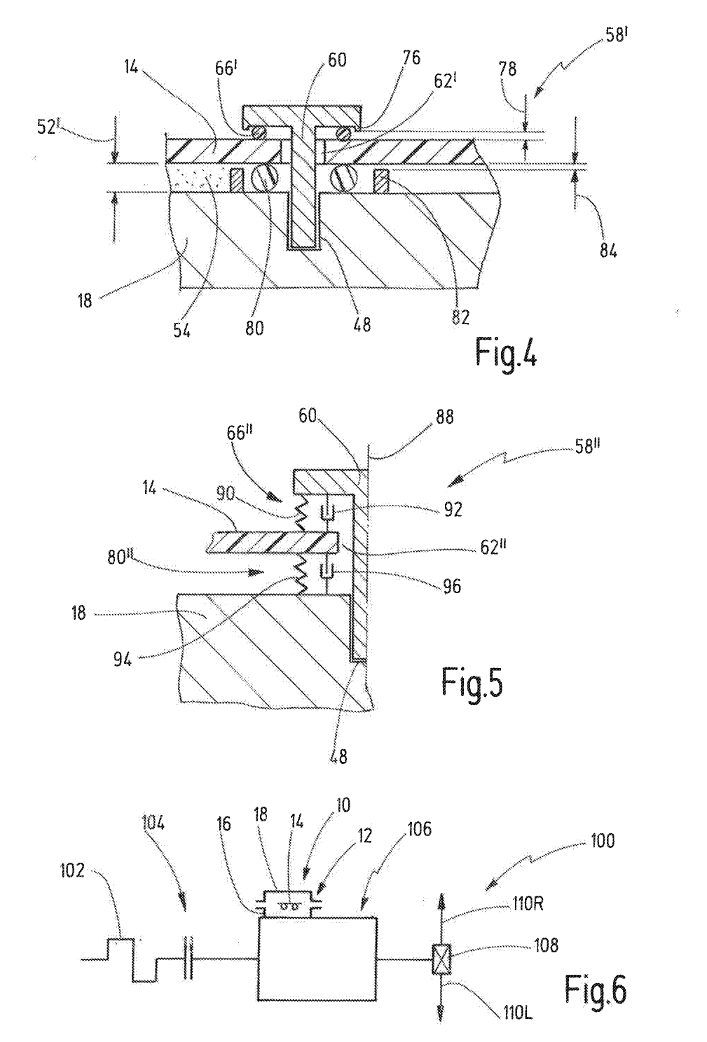

FIG. 4 shows an alternative embodiment of a peripheral fastening device 58′.

In the peripheral fastening device of FIG. 4, a stop element 76 is formed on an underside of a head of the peripheral fastening bolt, which stop element 76 defines a maximum deflection 78 between the head of the peripheral fastening bolt 60 and the printed circuit board 14.

Furthermore, with the peripheral fastening device 58′ of FIG. 4, another peripheral fastening element 80 is arranged between the axial side of the printed circuit board 14 which faces the housing cover 18 (circuit board carrier) and the housing cover 18. The further peripheral fastening element 80 may also be formed as a spring element and/or as a damper element, particularly as an elastic element such as an O-ring.

Due to the additional peripheral fastening element 80, the printed circuit board 14 may also move elastically with respect to the circuit board carrier 18. The maximum deflection 84 between the printed circuit board 14 and the circuit board carrier (housing cover) 18 can be defined by a further stop element 82.

The distance 52′ between the printed circuit board 14 and the circuit board carrier 18 is therefore variable within narrow limits (within the maximum deflection 84) in this embodiment. The heat-conducting material 54 is therefore preferably elastically deformable in this embodiment.

FIG. 5 shows in a schematic manner a further embodiment of a peripheral fastening device 58″.

Here, it is shown in general schematic form that a printed circuit board 14 can be fastened by means of a peripheral fastening bolt 60 to a circuit board carrier in the form of a housing cover 18, wherein the bolt 60 extends along a longitudinal axis 88 which extends transversely to a tangential direction or to an extension of the printed circuit board 14. A spring element 90 and a damper element 92, which together form a peripheral fastening element 66″, are indicated in schematic form between a head of the peripheral fastening bolt 60 and the printed circuit board 14.

Correspondingly, a spring element 94 and a damper element 96 are provided between the printed circuit board 14 and the circuit board carrier 18, which spring element 94 and damper element 96 together form a further peripheral fastening element 80″.

The spring elements 90, 94 provide elastic relative movability between the printed circuit board 14 and the circuit board carrier 18 and the peripheral fastening stud(s). The damper elements 92, 96 dampen such relative movements. The spring elements 90, 94, further, define a standard or normal position of the printed circuit board 14 in relation to the circuit board carrier 18.

The peripheral fastening device 58″ schematically shown in FIG. 5 can have, as a peripheral fastening element 66″ and/or as a further peripheral fastening element 80″, an elastically deformable element such as a ring element made of rubber or an elastically deformable plastic material.

In FIG. 6, a drive train 100 for a motor vehicle is shown in schematic form. The drive train 100 comprises a drive motor 102 whose output is connected to the input of a clutch arrangement 104. An output of the clutch arrangement 104 is connected to a transmission arrangement 106. An output of the transmission arrangement 106 is connected to a differential 108, by means of which drive power can be distributed to driven wheels 110L, 110R.

The transmission arrangement 106 comprises a housing, on the outside of which an electronic module 10 is arranged. FIG. 6 shows that a housing base 16 of the electronic module can be rigidly connected to a housing of the transmission arrangement 106, and shows that a housing cover 18 covers an interior of a housing arrangement 12 in which a printed circuit board 14 is arranged.

The electronic module can be one of the electronic modules described above, or can be an electronic module which is equipped with embodiments of circuit board arrangements as described below.

For example, FIG. 7 shows a schematic sectional view through another embodiment of a central fastening device 42″.

The central fastening device 42″ of FIG. 7 is used for fastening a printed circuit board 14 as well as another printed circuit board 114 in relation to a circuit board carrier 18, which is for example in the form of a cover.

The printed circuit board 14 can be fastened as is described above in relation to FIG. 1. A spacer sleeve 116 can be provided between the printed circuit board 14 and the further printed circuit board 114, which is arranged essentially parallel thereto, which spacer sleeve 116 contains a circuit board receptacle 118 for the lower printed circuit board 14 and a second circuit board receptacle 120 for the further printed circuit board 114, in such a way that these can be aligned coaxially to a longitudinal axis 88 with their recesses 46″ or 121.

The head of the bolt 44 contacts the top side of the further printed circuit board 114. The printed circuit board 14 rests on a spacer element 50 so that a distance which is not specified in detail and which is provided for a heat-conducting paste 54 between the circuit board 14 and the circuit board carrier 18 is established, in a manner similar to the previous embodiments.

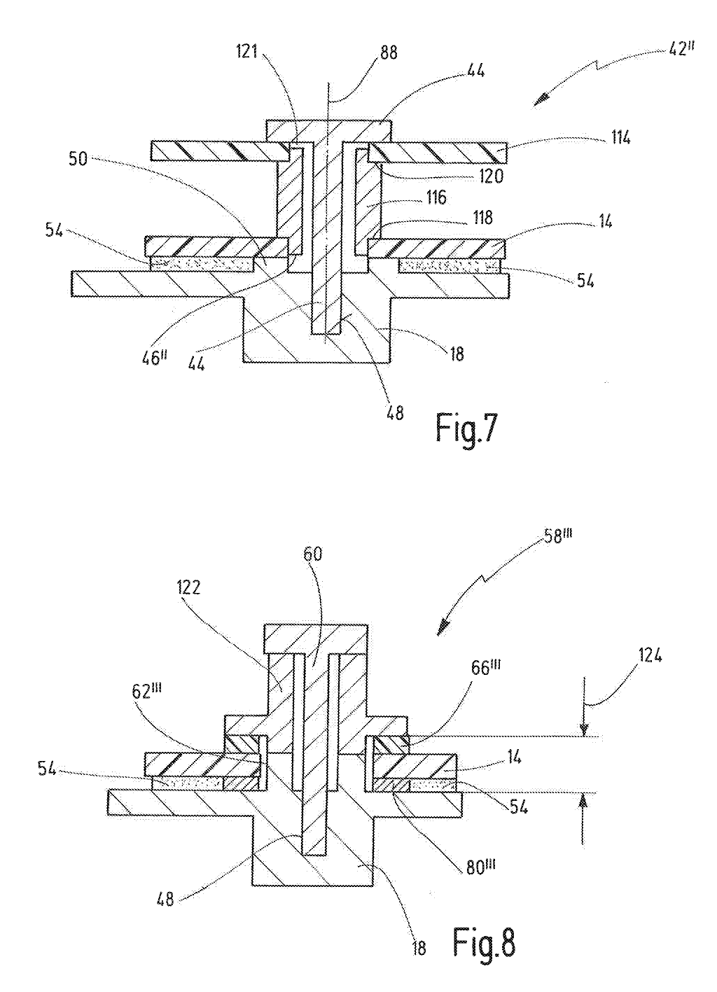

FIG. 8 shows another embodiment of a peripheral fastening device 58′″, wherein a printed circuit board 14 can be fastened in relation to a circuit board carrier 18 by means of a peripheral fastening element 66′″ and by means of a further peripheral fastening element 80′″, in a manner similar to the embodiments of FIG. 4 or FIG. 5.

In addition, a clamping sleeve 122 is provided, which is arranged between the head of the peripheral fastening bolt 60 and a spacer element not specified in detail, which clamping sleeve can be formed integrally with the circuit board carrier 18. A defined distance may therefore be established between a top side of the upper peripheral fastening element 66′″ and a lower side of the lower further peripheral fastening element 80′″ by means of the clamping sleeve 122, so that a defined preload of these elements can be set up to support the printed circuit board 14.

1. A circuit board arrangement comprising a printed circuit board and a circuit board carrier on which the printed circuit board is mounted, the printed circuit board having a central region and a peripheral region,
wherein the printed circuit board is held in the central region on the circuit board carrier in a tangential direction in a positive-locking manner, and wherein the circuit board is held in the peripheral region on the circuit board carrier in the tangential direction with a transverse force in a non-positive manner.

2. The circuit board arrangement according to claim 1, wherein the printed circuit board is displaceably mounted in the peripheral region in a tangential direction relative to the circuit board carrier.

3. The circuit board arrangement according to claim 1, wherein the transverse force is generated by an axial clamping device.

4. The circuit board arrangement according to claim 1, wherein the printed circuit board is held in the peripheral region by at least one of a spring element and a damping element with respect to the circuit board carrier.

5. The circuit board arrangement according to claim 4, wherein the at least one of a spring element and a damper element establishes an electrical connection between the printed circuit board and the circuit board carrier.

6. The circuit board arrangement according to claim 1, wherein the circuit board carrier has a planar portion facing towards the printed circuit board and being aligned substantially parallel thereto, wherein the circuit board carrier serves as a heat sink and wherein a thermally conductive material is arranged between the printed circuit board and the planar portion.

7. The circuit board arrangement according to claim 6, wherein the thermally conductive material is formed as a paste.

8. The circuit board arrangement according to claim 1, wherein the circuit board carrier has a planar portion facing towards the printed circuit board and being aligned substantially parallel thereto, wherein the circuit board carrier serves as a heat sink and wherein a thermally conductive material is arranged between the printed circuit board and the planar portion, wherein the thermally conductive material is formed as a paste, and wherein the planar portion of the circuit board carrier is arranged essentially between the central region and the peripheral region.

9. The circuit board arrangement according to claim 6, wherein the thermally conductive material contains beads of an electrically insulating material whose diameter ensures a minimum layer thickness of the thermally conductive material.

10. A circuit board arrangement comprising a printed circuit board and a circuit board carrier on which the printed circuit board is mounted the printed circuit board having a central region and a peripheral region, wherein
the printed circuit board is held in the central region on the circuit board carrier in a tangential direction with a first transverse force in a non-positive manner, the circuit board being held in the peripheral region on the circuit board carrier in the tangential direction with a second transverse force in a non-positive manner which second transverse force is smaller than the first transverse force.

11. The circuit board arrangement according to claim 10, wherein the printed circuit board is displaceably mounted in at least one of the peripheral region and the central region in a tangential direction relative to the circuit board carrier.

12. The circuit board arrangement according to claim 10, wherein at least one of the first transverse force and the second transverse force is generated by a respective axial clamping device.

13. The circuit board arrangement according to claim 10, wherein the printed circuit board is held in the peripheral region by at least one of a spring element and a damping element with respect to the circuit board carrier.

14. The circuit board arrangement according to claim 13, wherein the at least one of a spring element and a damping element establishes an electrical connection between the printed circuit board and the circuit board carrier.

15. A circuit board arrangement according to claim 1, wherein the circuit board carrier has a planar portion facing towards the printed circuit board and being aligned substantially parallel thereto, wherein the circuit board carrier serves as a heat sink and wherein a thermally conductive material is arranged between the printed circuit board and the planar portion.

16. The circuit board arrangement according to claim 15, wherein the thermally conductive material is formed as a paste.

17. The circuit board arrangement according to claim 15, wherein the planar portion of the circuit board carrier is arranged essentially between the central region and the peripheral region.

18. The circuit board arrangement according to claim 15, wherein the thermally conductive material contains beads of an electrically insulating material whose diameter ensures a minimum layer thickness of the thermally conductive material.

19. A drive train for a motor vehicle, having an electronic module which is adapted to control at least one part of the drive train, the electronic module having a housing in which a circuit board arrangement is accommodated, the circuit board arrangement comprising a printed circuit board and a circuit board carrier on which the printed circuit board is mounted, the printed circuit board having a central region and a peripheral region,
wherein the printed circuit board is held in the central region on the circuit board carrier in a tangential direction in a positive-locking manner, and wherein, the circuit board is held in the peripheral region on the circuit board carrier in the tangential direction with a transverse force in a non-positive manner.
